(19) United States
(12) Patent Application Publication
(10) Pub. No.: US 2026/0095179 A1
(43) Pub. Date: Apr. 2, 2026

(54) MEMS Switch Actuation Protection Circuit

(71) Applicant: Cenfire Corp, Goleta, CA (US)

(72) Inventors: Soheil Seena Partokia, Goleta, CA (US); Daniel Julian Arroyo, Santa Barbara, CA (US)

(73) Assignee: Cenfire Corp, Goleta, CA (US)

(21) Appl. No.: 19/338,627

(22) Filed: Sep. 24, 2025

Related U.S. Application Data
(60) Provisional application No. 63/701,118, filed on Sep. 30, 2024.

(51) Int. Cl. H03K 17/74; B81B 7/00

(52) U.S. Cl. CPC H03K 17/74; B81B 7/008

(57) ABSTRACT

An apparatus includes a microelectromechanical systems (MEMS) switch having input, output, gate, and beam nodes, a Zener diode connected to the gate node, and a pull-down resistor connected between the gate node and a bias voltage node. The Zener diode is configured to limit a bias voltage difference between the gate and beam nodes to not exceed a voltage level that is about equal to its breakdown voltage, the breakdown voltage being selected at or slightly above an actuation threshold of the MEMS switch. The pull-down resistor is configured to pull the gate node toward the bias voltage when the bias voltage difference is below the actuation threshold.

### RELATED APPLICATIONS

This application claims priority to U.S. Provisional Ser. No. 63/701,118, filed Sep. 30, 2024, all of which is incorporated by reference herein in its entirety.

### BACKGROUND

Microelectromechanical systems (MEMS) relay switches are known for their superior performance in terms of switching speed, power efficiency, and integration capabilities with semiconductor technologies as compared to conventional electromagnetic relays. A conventional MEMS relay switch includes one or more input nodes, one or more output nodes, a gate node, and a beam node.

The operation of these switches is based on the principle of electrostatic actuation. By applying a voltage differential between the gate and beam terminals (e.g., 65V), an electrostatic force is generated, causing the beam to move and thereby open or close the circuit between the input and output nodes. This mechanism allows for precise control over the switch's state (on or off) with minimal power consumption.

### SUMMARY

In some aspects, the techniques described herein relate to an apparatus including: a first microelectromechanical systems (MEMS) switch having an input node, an output node, a gate node, and a beam node; a first Zener diode having a first terminal directly electrically connected to the gate node of the first MEMS switch, the first terminal being one of an anode terminal or a cathode terminal of the first Zener diode; and a first pull-down resistor having a first terminal directly electrically connected to the gate node of the first MEMS switch and a second terminal directly electrically connected to a bias voltage at a first voltage node; wherein the first Zener diode is configured to limit a magnitude of a bias voltage difference between the gate node and the beam node of the first MEMS switch to be not greater than a clamp level about equal to a breakdown voltage of the first Zener diode, the breakdown voltage being selected to be at or slightly above an actuation voltage threshold of the first MEMS switch; and wherein the first pull-down resistor is configured to pull the gate node toward the bias voltage when the magnitude of the bias voltage difference between the gate node and the beam node is less than the actuation voltage threshold of the first MEMS switch.

In some aspects, the techniques described herein relate to an apparatus including: a first microelectromechanical systems (MEMS) switch having an input node, an output node, a gate node, and a beam node; an optional first Zener diode having a first terminal directly electrically connected to the gate node of the first MEMS switch, the first terminal being one of an anode terminal of the optional first Zener diode or a cathode terminal of the optional first Zener diode; and a first pull-down resistor having a first terminal directly electrically connected to the gate node of the first MEMS switch and a second terminal directly electrically connected to a bias voltage at a first voltage node.

### BRIEF DESCRIPTION OF THE DRAWINGS

FIG. 1 is a simplified circuit schematic showing an operational context for one or more MEMS relay switches, in accordance with some examples.

FIG. 2 is a simplified schematic of a MEMS relay switch that implements the MEMS relay switch shown in FIG. 1, in accordance with some examples.

FIG. 3A shows a first topology of a MEMS actuation protection circuit for the MEMS relay switch shown in FIG. 2, in accordance with some examples.

FIG. 3B shows a second topology of a MEMS actuation protection circuit for the MEMS relay switch shown in FIG. 2, in accordance with some examples.

FIG. 4A shows a third topology of a MEMS actuation protection circuit for the MEMS relay switch shown in FIG. 2, in accordance with some examples.

FIG. 4B shows a fourth topology of a MEMS actuation protection circuit for the MEMS relay switch shown in FIG. 2, in accordance with some examples.

FIG. 5A shows a fifth topology of a MEMS actuation protection circuit for the MEMS relay switch shown in FIG. 2, in accordance with some examples.

FIG. 5B shows a sixth topology of a MEMS actuation protection circuit for the MEMS relay switch shown in FIG. 2, in accordance with some examples.

FIG. 6 is a simplified circuit schematic showing a temperature and process-invariant high-voltage MEMS switch, in accordance with some examples.

FIG. 7 is a simplified schematic for a first topology of the temperature and process invariant high-voltage MEMS switch shown in FIG. 6, in accordance with some examples.

FIG. 8 is a simplified schematic for a second topology of the temperature and process invariant high-voltage MEMS switch shown in FIG. 6, in accordance with some examples.

FIGS. 9A-9B provide example switching sequences for controlling the high-voltage MEMS switch shown in FIG. 6, in accordance with some examples.

### DETAILED DESCRIPTION

While conventional MEMS relay switches offer significant advantages, such as low power consumption, excellent RF performance, and compact size, there are notable challenges that impact their performance and longevity. One of the primary concerns is the management of the bias voltage differential between the gate and beam terminals, referred to herein as an actuation voltage. The application of an excessive actuation voltage for a MEMS relay switch beyond a required actuation voltage threshold may lead to an immediate failure of the switch or may reduce the usable life of the switch.

As a first example, an excessive actuation voltage may cause the beam to adhere to the gate, a phenomenon known as stiction, which can permanently damage the switch or significantly reduce its operational lifespan. As a second example, an excessive actuation voltage may lead to dielectric breakdown in the insulating layers of the MEMS relay switch, compromising the switch's reliability and leading to failure. As a third example, an excessive actuation voltage may increase the risk of electrostatic discharge (ESD), which can cause immediate failure of the switch or degrade its performance over time. Additionally, repeated application of excessive actuation voltages can lead to material fatigue, reducing the mechanical integrity of the switch components.

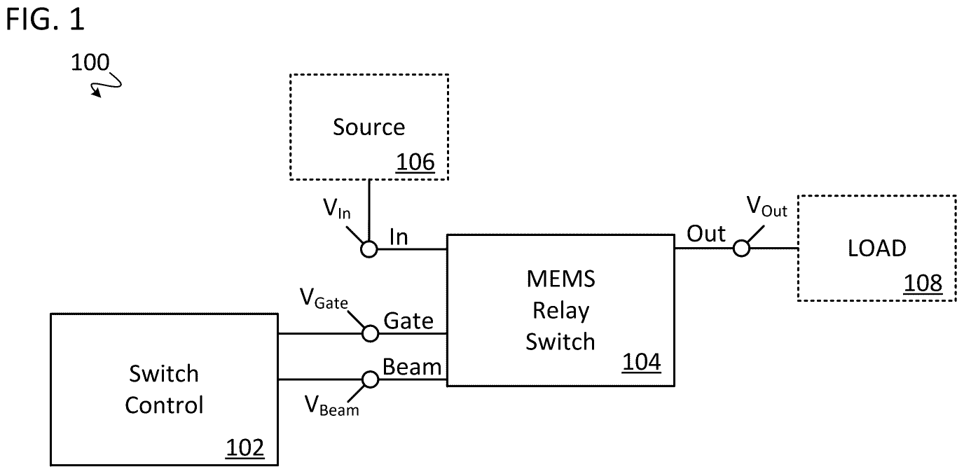

FIG. 1 is a simplified circuit schematic 100 showing an operational context for one or more MEMS relay switches (“MEMS switches”) 104, in accordance with some examples. The circuit 100 includes a switch control circuit 102, the MEMS switch 104, an upstream voltage signal source 106, and a downstream load 108, coupled as shown. The MEMS switch 104 includes a gate node (“Gate”), a beam node (“Beam”), an input node (“In”), and an output node (“Out”).

As shown, the switch control circuit 102 is operable to provide a first control signal V_{Gate} to the gate node of the MEMS switch 104 and a second control or bias voltage signal V_{Beam} to the beam node of the MEMS switch 104. The control signals V_{Gate} and V_{Beam} are operable to develop an electrostatic voltage differential across the gate and beam nodes of the MEMS switch 104 to control the actuation thereof. When the MEMS switch 104 is enabled, the input and output nodes of the MEMS switch 104, “In” and “Out”, are galvanically connected. When the MEMS switch 104 is disabled, the input and output nodes of the MEMS switch 104 are galvanically isolated.

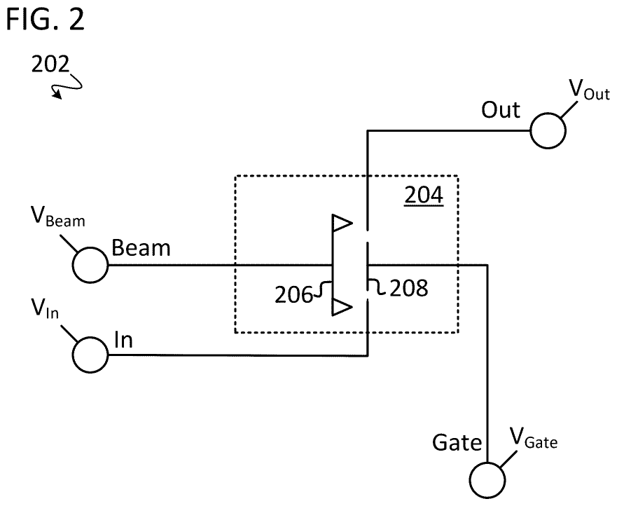

FIG. 2 is a simplified schematic 202 of a MEMS switch 204 which implements the MEMS switch 104 shown in FIG. 1, in accordance with some examples. Generally, a MEMS switch contains two contacts—one of which is rigid and stationary (i.e., a gate 208), and one of which is moveable or flexible (i.e., a beam 206). To close the circuit, the beam 206 is drawn to the stationary gate 208 by an electrostatic force triggered by a control voltage developed across the gate and beam nodes via V_{Gate} and V_{Beam}. When the control voltage is removed, the beam 206 returns to its original position, opening the circuit.

In some use scenarios, the beam 206 can be grounded, or it can be biased to another voltage potential via V_{Beam}. This is because only relative terminal voltages are important for actuating the MEMS switch 204, not absolute voltages. The MEMS switch 204 is actuated when a bias potential difference between the gate node, via V_{Gate}, and the beam node, via V_{Beam}, is greater than or equal to the actuation voltage threshold for the MEMS switch 204 (e.g., 65V). Either positive or negative values of (V_{Gate}−V_{Beam}) will actuate the device, i.e., it has symmetric behavior for the absolute value |V_{Gate}−V_{Beam}|.

Unfortunately, an excessive actuation voltage level (i.e., a bias voltage difference that is significantly greater than the actuation voltage threshold) may lead to several issues that may cause an immediate or premature failure of the MEMS switch 204. As described above, such issues include stiction and adhesion, dielectric breakdown, electrostatic discharge (ESD) damage, and material fatigue. Disclosed herein are MEMS actuation protection circuits that advantageously limit a maximum actuation voltage for a MEMS switch for a variety of input voltage, output voltage, and load scenarios.

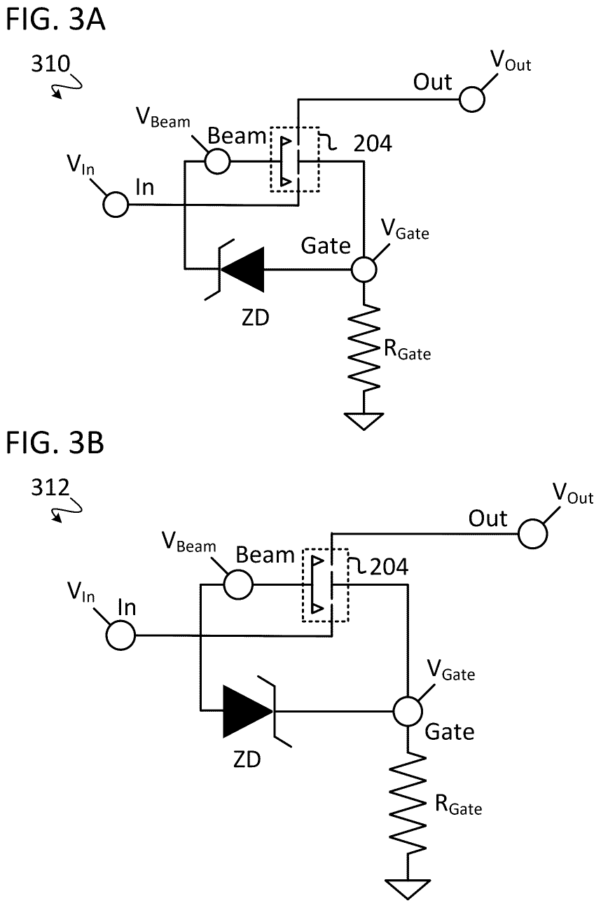

FIG. 3A shows a first topology 310 of a MEMS actuation protection circuit for the MEMS switch 204, in accordance with some examples. The MEMS actuation protection circuit 310 includes a Zener diode ZD and a pull-down resistor R_{Gate}, connected as shown. Also shown are switch nodes of the MEMS switch 204 and voltage signals related to the operation thereof. The switch nodes are labeled “In”, “Out”, “Beam”, and “Gate”. The respective voltage signals are designated as V_{In}, V_{Out}, V_{Beam}, and V_{Gate}.

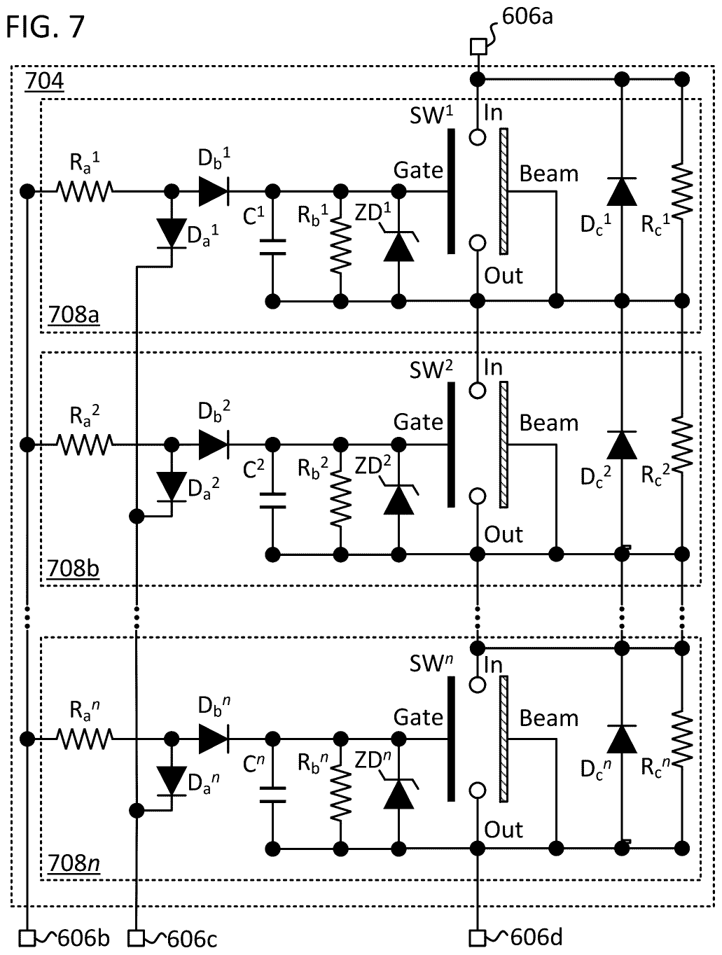

In the topology shown, the input node “In” is directly electrically connected to the beam node “Beam”and to a cathode terminal of the Zener diode ZD. An anode terminal of the Zener diode ZD is directly electrically connected to the gate node “Gate” and to a first terminal of the pull-down resistor R_{Gate}. A second terminal of the pull-down resistor R_{Gate} is directly electrically connected to a voltage node, such as ground, or to another node of another circuit, such as shown in FIG. 7. The output node “Out”may be connected to a load (such as the load 108, not shown).

The topology 310 is operable for use cases in which an input voltage signal V_{In} is greater than or equal to 0 Volts. The Zener diode ZD is configured to have a reverse breakdown voltage V_{Zener} that is equal to or greater than the actuation voltage threshold of the MEMS switch 204.

When the input voltage V_{In} is less than the reverse breakdown voltage V_{Zener} of the Zener diode ZD in FIG. 3A, the MEMS switch 204 is off and the voltage signal V_{Gate} is pulled to 0 Volts via the pull-down resistor R_{Gate}. When the input voltage signal Vᵢₙ is greater than the reverse breakdown voltage V_{Zener} of the Zener diode ZD, the MEMS switch 204 is actuated, and (V_{Beam}−V_{Gate}) is equal to the reverse breakdown voltage V_{Zener}. If the input voltage signal V_{In} increases further, the voltage difference between V_{In} and V_{Gate} is advantageously limited to the reverse breakdown voltage V_{Zener}, thereby preventing an excess actuation voltage from being applied to the MEMS switch 204. The topology 310 assumes that the impedance from the output node “Out” to ground is high enough so as to not pull V_{In} below V_{Zener}. The pulldown resistor R_{Gate} advantageously keeps the gate voltage V_{Gate} at 0V when the input voltage V_{In} is less than V_{Zener}.

FIG. 3B shows a second topology 312 of a MEMS actuation protection circuit for the MEMS switch 204, in accordance with some examples. The second topology 312 is similar to the first topology 310 except for modifications to accommodate negative input voltage signals.

The actuation protection circuit 312 includes a Zener diode ZD having a breakdown voltage V_{Zener}, and a pull-down resistor R_{Gate}, connected as shown. Also shown are switch nodes of the MEMS switch 204 and voltage signals related to the operation thereof. The switch nodes are labeled “In”, “Out”, “Beam”, and “Gate”. The respective voltage signals are designated as V_{In}, V_{Out}, V_{Beam}, and V_{Gate}.

In the topology shown, the input node “In” is directly electrically connected to the beam node “Beam” and to an anode terminal of the Zener diode ZD. A cathode terminal of the Zener diode ZD is directly electrically connected to the gate node “Gate” and to a first terminal of the pull-down resistor R_{Gate}. A second terminal of the pull-down resistor R_{Gate} is directly electrically connected to a voltage node, such as ground. The output node “Out” may be connected to a load (such as the load 108, not shown).

The topology 312 is operable for use cases in which the input voltage signal V_{In} is negative to zero volts. As shown, the input node “In” is electrically connected to the beam node “Beam”. The Zener diode ZD is configured to set the gate voltage V_{Gate} based on the input voltage V_{In}. When the absolute value of the input voltage signal |V_{In}| is less than the Zener diode ZD breakdown voltage V_{Zener}, the MEMS switch 204 is off, and the gate voltage signal V_{Gate} is pulled to 0 Volts through the pull-down resistor R_{Gate}.

By comparison, when the absolute value of the input voltage |V_{In}| is greater than the Zener diode breakdown voltage V_{Zener}, the MEMS switch 204 in FIG. 3B actuates, and the bias potential difference between the gate node and the beam node, (V_{Gate}−V_{Beam}), is equal to the Zener diode breakdown voltage V_{Zener}. The difference between V_{In} and V_{Gate} is limited to V_{Zener} thereafter, preventing overdrive of the gate node to beam node voltages.

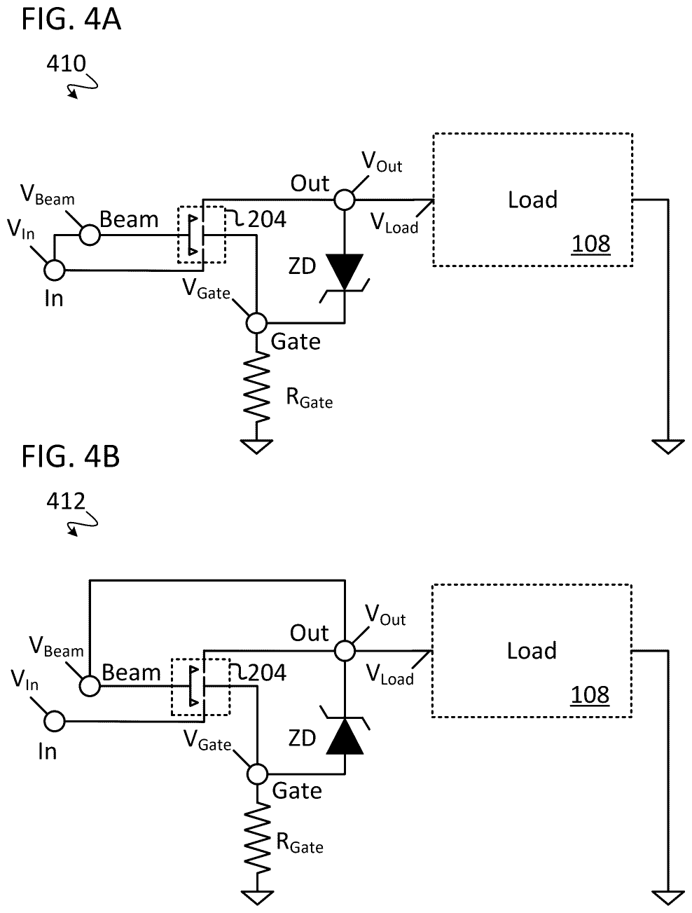

FIG. 4A shows a third topology 410 of a MEMS actuation protection circuit for the MEMS switch 204, in accordance with some examples. The topology 410 is operable for use cases in which a load voltage V_{Load} is less than zero volts (i.e., the load 108 is negative). The MEMS actuation protection circuit 410 includes a Zener diode ZD having a breakdown voltage V_{Zener}, and a pull-down resistor R_{Gate}, connected as shown. Also shown are the switch nodes of the MEMS switch 204, voltage signals related to the operation thereof, and the load 108. The switch nodes are labeled “In”, “Out”, “Beam”, and “Gate”. The respective voltage signals are designated as V_{In}, V_{Out}, V_{Beam}, V_{Gate}, and V_{Load}.

In the topology shown, the input node “In” is directly electrically connected to the beam node “Beam.” The output node “Out” is directly electrically connected to an anode terminal of the Zener diode ZD. A cathode terminal of the Zener diode ZD is directly electrically connected to the gate node “Gate” and to a first terminal of the pull-down resistor R_{Gate}. A second terminal of the pull-down resistor R_{Gate} is directly electrically connected to a voltage node, such as ground. The output node “Out” may be connected to a load, such as the load 108, as shown.

When the absolute value of the load voltage |V_{Load}| is less than the Zener diode ZD breakdown voltage V_{Zener}, the MEMS switch 204 of FIG. 4A is off, and the gate voltage signal V_{Gate} is pulled to 0 Volts through the pull-down resistor R_{Gate}. As long as VLoad is greater than the Zener diode ZD breakdown voltage V_{Zener}, (V_{Beam}−V_{Gate}) is limited to the Zener diode breakdown voltage V_{Zener}. The difference between V_{In} and V_{Gate} is limited to V_{Zener} thereafter, preventing overdrive of the gate node to beam node voltages.

FIG. 4B shows a fourth topology 412 of a MEMS actuation protection circuit for the MEMS switch 204, in accordance with some examples. The topology 412 is operable for use cases in which V_{Load} is greater than zero volts (i.e., the load 108 is positive), and the load 108 has a varying impedance. The MEMS actuation protection circuit includes a Zener diode ZD having a breakdown voltage V_{Zener}, and a pull-down resistor R_{Gate}, connected as shown. Also shown are the switch nodes of the MEMS switch 204, voltage signals related to the operation thereof, and the load 108. The switch nodes are labeled “In”, “Out”, “Beam”, and “Gate”. The respective voltage signals are designated as V_{In}, V_{Out}, V_{Beam}, V_{Gate}, and V_{Load}.

In the topology shown, the output node “Out” is directly electrically connected to the beam node “Beam”and to a cathode terminal of the Zener diode ZD. An anode terminal of the Zener diode ZD is directly electrically connected to the gate node “Gate” and to a first terminal of the pull-down resistor R_{Gate}. A second terminal of the pull-down resistor R_{Gate} is directly electrically connected to a voltage node, such as ground. The output node “Out” may be connected to a load, such as the load 108, as shown.

In the example shown, the output node “Out” of the MEMS switch 204 is electrically connected to the beam node “Beam”. The example shown assumes that the Zener diode breakdown voltage V_{Zener} is equal to or greater than the actuation voltage of the MEMS switch 204.

When V_{Out} is less than the Zener diode breakdown voltage V_{Zener}, the switch 204 in FIG. 4B is off, and the gate voltage V_{Gate} is pulled to 0 volts through the pull-down resistor R_{Gate}. By comparison, when V_{Out} is greater than the Zener diode breakdown voltage V_{Zener}, the switch 204 is on and (V_{Gate}−V_{Beam}) is equal to the Zener diode breakdown voltage V_{Zener}. The difference between V_{In} and V_{Gate} is limited to V_{Zener} thereafter, preventing overdrive of the gate node to beam node voltages. However, this topology assumes that the varying impedance of the load 108 remains high enough to prevent pulling the input voltage V_{In} down. The pull-down resistor R_{Gate} keeps V_{Gate} at 0 Volts when the absolute value of the load voltage signal |V_{Load}| is less than the Zener diode breakdown voltage V_{Zener}.

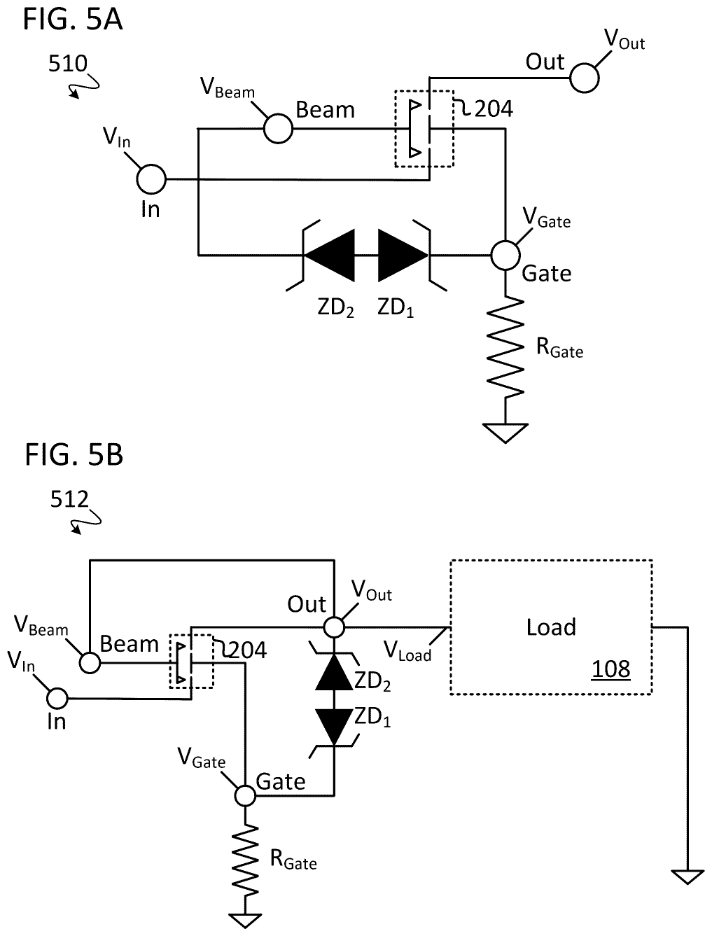

FIG. 5A shows a fifth topology 510 of a MEMS actuation protection circuit for the MEMS switch 204, in accordance with some examples. The MEMS actuation protection circuit includes back-to-back Zener diodes ZD₁₋₂, each having the same respective breakdown voltages V_{Zener}, and a pull-down resistor R_{Gate}, connected as shown. Also shown are switch nodes of the MEMS switch 204, and voltage signals related to the operation thereof. The switch nodes are labeled “In”, “Out”, “Beam”, and “Gate”. The respective voltage signals are designated as V_{In}, V_{Out}, V_{Beam}, and V_{Gate}.

In the topology shown, the input node “In” is directly electrically connected to the beam node “Beam”and to a cathode terminal of the Zener diode ZD₂. An anode terminal of the Zener diode ZD₂ is directly electrically connected to an anode terminal of the Zener diode ZD₁. A cathode terminal of the Zener diode ZD₁ is directly electrically connected to the gate node “Gate” and to a first terminal of the pull-down resistor R_{Gate}. A second terminal of the pull-down resistor R_{Gate} is directly electrically connected to a voltage node, such as ground. The output node “Out” may be connected to a load, such as the load 108 (not shown).

The back-to-back Zener diodes ZD₁₋₂ set the gate voltage V_{Gate} for either a positive or negative voltage level of the input voltage V_{In}. When the input voltage V_{In} is less than the Zener diode breakdown voltage V_{Zener} of the Zener diodes ZD₁₋₂, the MEMS switch 204 of FIG. 5A is off, and the gate voltage V_{Gate} is pulled to 0 volts through the pull-down resistor R_{Gate}. When the input voltage V_{In} is greater than the Zener diode's breakdown voltage V_{Zener}, the reverse-biased Zener diode of the Zener diodes ZD₁₋₂ breaks down and the forward-biased Zener diode of the Zener diodes ZD₁₋₂ conducts, thereby actuating the MEMS switch 204.

The sum of the Zener diode breakdown voltage V_{Zener} of the reverse biased Zener diode, plus a forward bias voltage V_{Zfwd} of the forward biased Zener diode (which is very small compared to V_{Zener}), sets (V_{Gate}−V_{Beam}) roughly equal to the Zener diode breakdown voltage V_{Zener}. The difference between V_{In} and V_{Gate} is limited to roughly V_{Zener} thereafter, preventing overdrive of the gate node to beam node voltages. The pull-down resistor R_{Gate} keeps V_{Gate} at 0 Volts when the absolute value of the load voltage |V_{In}| is less than the Zener diode breakdown voltage V_{Zener}.

FIG. 5B shows a sixth topology 512 of a MEMS actuation protection circuit for the MEMS switch 204, in accordance with some examples. The topology 512 is operable for use cases in which the load 108 has a varying impedance.

The MEMS actuation protection circuit includes back-to-back Zener diodes ZD₁₋₂, each having the same breakdown voltages V_{Zener}, and a pull-down resistor R_{Gate}, connected as shown. Also shown are the switch nodes of the MEMS switch 204, voltage signals related to the operation thereof, and the load 108. The switch nodes are labeled “In”, “Out”, “Beam”, and “Gate”. The respective voltage signals are designated as V_{In}, V_{Out}, V_{Beam}, V_{Gate}, and V_{Load}.

In the topology shown, the output node “Out” is directly electrically connected to the beam node “Beam”and to a cathode terminal of the Zener diode ZD₂. An anode terminal of the Zener diode ZD₂ is directly electrically connected to an anode terminal of the Zener diode ZD₁. A cathode terminal of the Zener diode ZD₁ is directly electrically connected to the gate node “Gate” and to a first terminal of the pull-down resistor R_{Gate}. A second terminal of the pull-down resistor R_{Gate} is directly electrically connected to a voltage node, such as ground. The output node “Out” may be connected to a load, such as the load 108 as shown.

The back-to-back Zener diodes ZD₁₋₂ set the voltage difference (V_{Gate}−V_{Beam}) to be roughly equal to the Zener diode breakdown voltage V_{Zener} for positive or negative voltage levels of V_{Load}. When the absolute value of the load voltage |V_{Load}| is greater than the Zener diode breakdown voltages V_{Zener} of the reverse biased Zener diode plus a forward bias voltage V_{Zfwd} of the forward biased Zener diode (which is very small compared to V_{Zener}), the reverse biased Zener diode of the Zener diodes ZD₁₋₂ breaks down, and the forward biased Zener diode of the Zener diodes ZD₁₋₂ conducts, thereby actuating the MEMS switch 204. The sum of the Zener diode breakdown voltage V_{Zener} plus the forward bias voltage V_{Zfwd} sets (V_{Beam}−V_{Gate}) roughly equal to the Zener diode breakdown voltage V_{Zener}. The difference between V_{Beam} and V_{Gate} is clamped to V_{Zener} thereafter, preventing overdrive of the gate node to beam node voltages. The pull-down resistor R_{Gate} keeps V_{Gate} at 0 Volts when the absolute value of the load voltage |V_{Load}| is less than the Zener diode breakdown voltage V_{Zener}.

Though the MEMS actuation protection circuit topologies disclosed above advantageously protect the MEMS switch 204 from overvoltage conditions across the gate and beam nodes, the Zener diode breakdown voltage V_{Zener} may vary from part-to-part and across temperature changes. Therefore, disclosed herein is a temperature and process invariant MEMS actuation protection circuit that advantageously reduces gate bias voltage variations for a given MEMS switch 204 induced by the variation in the Zener diode breakdown voltage V_{Zener}.

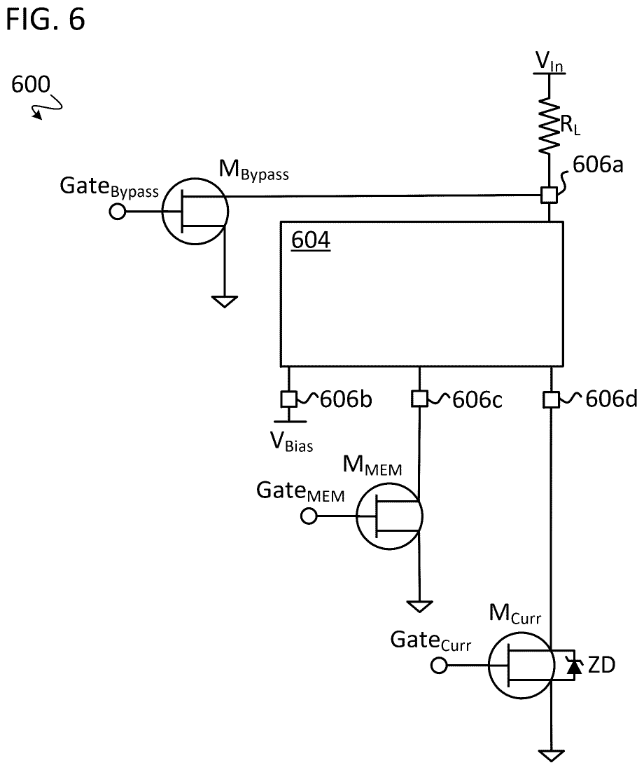

FIG. 6 is a simplified circuit schematic 600 showing high-level details of a temperature and process invariant high-voltage MEMS switch 604, in accordance with some examples. The circuit 600 includes an input isolation switch M_{Bypass}, a MEMS gate control switch M_{MEM}, an output current switch M_{Curr}, a Zener diode ZD, and a resistor R_{L}, connected as shown. Also shown are circuit nodes 606a-d, and signals Gate_{Bypass}, Gate_{MEM}, Gate_{Curr}, V_{In}, and V_{Bias}. Details of the high-voltage MEMS switch 604 are described below.

FIG. 7 is a simplified schematic for a first topology of a temperature and process invariant high-voltage MEMS switch 704 which implements the high-voltage MEMS switch 604 shown in FIG. 6, in accordance with some examples.

The high-voltage MEMS switch 704 includes n switch cells 708a-n for respective MEMS switches SW¹⁻ⁿ, each of which is similar to the MEMS switch 204, and each having an input node “In”, an output node “Out”, a gate node “Gate”, and a beam node “Beam”. Each of the switch cells 708a-n includes i) respective series resistors Rₐ¹⁻ⁿ, ii) respective current steering diodes Dₐ¹⁻ⁿ and D_{b}¹⁻ⁿ, iii) respective gate node bias clamping circuits, each having a parallel capacitor C¹⁻ⁿ, a respective parallel resistor R_{b}¹⁻ⁿ, and a respective parallel Zener diode ZD¹⁻ⁿ, and iv) respective beam node bias circuits, each having a parallel diode D_{C}¹⁻ⁿ, and a parallel resistor R_{C}¹⁻ⁿ.

Values of the respective parallel capacitors C¹⁻ⁿ resistors R_{b}¹⁻ⁿ are configured to set a desired RC time constant for switch actuation to ensure that the associated switch of the MEMS switches SW¹⁻ⁿ is enabled in accordance with a desired time delay (i.e., not too rapidly to prevent mechanical damage thereto). Values of the diodes D_{C}¹⁻ⁿ and resistors R_{C}¹⁻ⁿ are configured to ensure that the input voltage at the node 606a is divided equally between each of the switch cells 708a-n. The Zener diodes ZD¹⁻ⁿ are operable to prevent an excess actuation voltage from being applied to the corresponding MEMS switches SW¹⁻ⁿ.

The use of multiple switch cells 708a-n enables a designer of the high-voltage MEMS switch to achieve a desired voltage rating (i.e., a rated voltage, maximum switching voltage, and/or contact rating). For example, if each of the switch cells 708a-n is configured to have a voltage rating of 200V, the high-voltage MEMS switch could include three of the switch cells 708a-n to achieve a voltage rating of 600V at the node 606a. Similarly, if each of the switch cells 708a-n is configured to have a voltage rating of 200V, the high-voltage MEMS switch could include four of the switch cells 708a-n to achieve a voltage rating of 800V at the node 606a, and so on.

As shown with respect to a first switch cell 708a, an input node “In” of the MEMS switch SW¹ is directly electrically connected to the circuit node 606a to receive an input voltage. A first terminal of the series resistor Rₐ¹ is directly electrically connected to the circuit node 606b to receive a gate bias voltage, and a second terminal of the series resistor Rₐ¹ is directly electrically connected to the anode terminals of the current steering diodes Dₐ¹ and D_{b}¹. A cathode terminal of the current steering diode Dₐ 1 is directly electrically connected to the circuit node 606c to control application of the bias voltage, and a cathode terminal of the current steering diode D_{b}¹ is directly electrically connected to a first terminal of the parallel capacitor C¹. The first terminal of the parallel capacitor C¹ is directly electrically connected to a first terminal of the parallel pulldown resistor R_{b}¹, a cathode terminal of the Zener diode ZD¹, and the gate node “Gate” of the MEMS switch SW¹. A second terminal of the parallel capacitor C¹ is directly electrically connected to a voltage node at a second terminal of the parallel resistor R_{b}¹, an anode terminal of the Zener diode ZD¹, and the output node “Out”of the MEMS switch SW¹. The input node “In” of the MEMS switch SW¹ is directly electrically connected to a cathode terminal of the parallel diode D_{C}¹ and a first terminal of the parallel resistor R_{C}¹. The output node “Out” of the MEMS switch SW¹ is directly electrically connected to the input node “In” of the MEMS switch SW² of the next cell 708b, the anode terminal of the parallel diode D_{C}¹, the voltage node at the second terminal of the parallel resistor R_{C}¹, a cathode terminal of a parallel diode D_{C}² of the next switch cell 708b, and a first terminal of the parallel resistor R_{C}² of the next switch cell 708b.

As described above, any number of similar switch cells may be configured in parallel between the switch cells 708a and 708n to achieve a desired voltage rating for the high-voltage MEMS switch 704. Although three switch cells are shown, one or two switch cells may also be used. Regarding the n^{th} switch cell 708n, an input node “In” of the MEMS switch SWⁿ is directly electrically connected to the output node “Out” of a MEMS switch in a preceding switch cell. A first terminal of the series resistor Rₐⁿ is directly electrically connected to the circuit node 606b, and a second terminal of the series resistor Rₐⁿ is directly electrically connected to the anode terminals of the current steering diodes Dₐⁿ and D_{b}ⁿ. A cathode terminal of the current steering diode Dₐⁿ is directly electrically connected to the circuit node 606c, and a cathode terminal of the current steering diode D_{b}ⁿ is directly electrically connected to a first terminal of the parallel capacitor Cⁿ. The first terminal of the parallel capacitor Cⁿ is directly electrically connected to a first terminal of the parallel pull-down resistor R_{b}ⁿ, a cathode terminal of the Zener diode ZDⁿ, and the gate node “Gate” of the MEMS switch SWⁿ. A second terminal of the parallel capacitor Cⁿ is directly electrically connected to a voltage node at a second terminal of the parallel resistor R_{b}ⁿ, an anode terminal of the Zener diode ZDⁿ, and the output node “Out”of the MEMS switch SWⁿ.

The input node “In” of the MEMS switch SWⁿ is directly electrically connected to the output node of the preceding switching cell, a cathode terminal of the parallel diode D_{C}ⁿ and a first terminal of the parallel resistor R_{C}ⁿ. The output node “Out” of the MEMS switch SWⁿ is directly electrically connected to the circuit node 606d, the anode terminal of the parallel diode D_{C}ⁿ, and a second terminal of the parallel resistor R_{C}ⁿ.

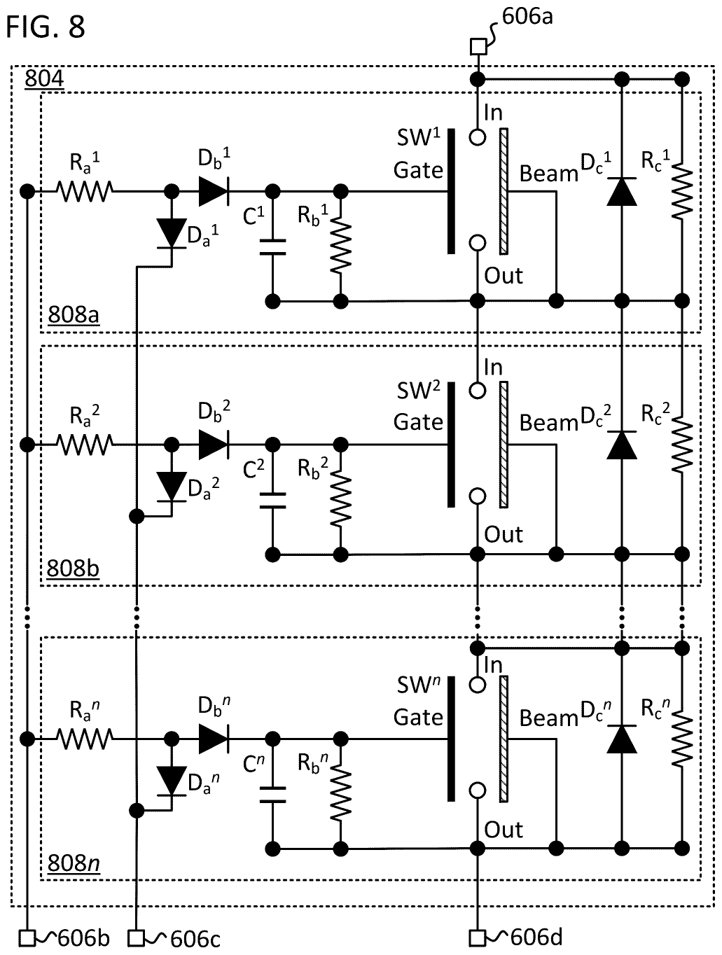

FIG. 8 is a simplified schematic for a second topology of a temperature and process invariant high-voltage MEMS switch 804 which implements the high-voltage MEMS switch 604 shown in FIG. 6, in accordance with some examples. The components of the high-voltage MEMS switch 804 are the same as those shown and described with reference to the high-voltage MEMS switch 704. However, in the example shown, the parallel Zener diodes ZD¹⁻ⁿ of the respective gate node bias clamping circuits shown in FIG. 7 have been omitted. The example shown in FIG. 8 is suitable for scenarios in which values of the resistors R_{B}¹⁻ⁿ and R_{C}¹⁻ⁿ may be configured to provide an appropriate gate bias voltage for the MEMS switches SW¹⁻ⁿ, thereby reducing cost as compared to configurations that include the parallel Zener diodes ZD¹⁻ⁿ.

The high-voltage MEMS switch 804 is simpler and less expensive as compared to the high-voltage MEMS switch 704, but a ratio of resistor values for the high-voltage MEMS switch 704 must be selected with more care as compared to the example shown in FIG. 7.

As was shown with reference to FIG. 6, node 606a of the high-voltage MEMS switches 604 is configured to receive an input voltage V_{In}, and node 606b is configured to receive a gate bias voltage V_{Bias} (e.g., 65V). The switches M_{Bypass}, M_{MEM}, and M_{Curr} are advantageously configured to prevent hot-switching of the high-voltage MEMS switch 604.

“Hot-switching” in MEMS relay switches refers to the act of making or breaking an electrical connection while under load, specifically when current is flowing or when there is a significant voltage difference across the relay contacts. This practice can lead to several issues specific to MEMS technology, including accelerated wear of the contact surfaces, potential welding of the contacts due to the high inrush currents, and degradation of the dielectric materials used in the construction of the switch. Such effects can severely limit the operational lifespan of MEMS relays, reduce their reliability, and compromise their switching accuracy and performance over time.

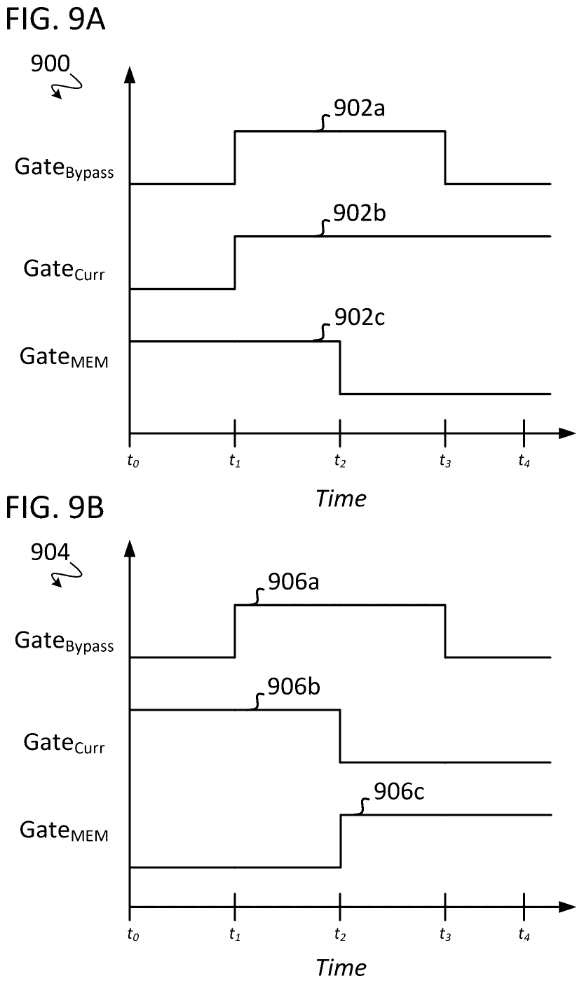

FIG. 9A provides an example switching sequence 900 that advantageously prevents hot-switching of the high-voltage MEMS switch (“switch”) 604 while enabling the high-voltage MEMS switch 604 (which could be implemented as either the high-voltage MEMS switch 704 or 804), in accordance with some examples.

With reference to FIG. 6, FIG. 9A provides a plot 902a of the gate control signal Gate_{Bypass} of the input isolation switch M_{Bypass}, a plot 902b of the gate control signal Gate_{Curr} of the output current switch M_{Curr}, and a plot 902c of the gate control signal Gate_{MEM} of the MEMS gate control switch M_{MEM}. In some examples, the gate control signals 902a-c are generated by a switch control circuit, such as the switch control circuit 102 introduced in FIG. 1.

At time t₀, the gate control signals Gate_{Bypass} 902 and Gate_{Curr} 902b are de-asserted and the gate control signal Gate_{MEM} 902c is asserted, thereby maintaining the switch 604 in an OFF state. To elaborate, with reference to FIGS. 7-8, the switch 604 is in an OFF state at time t₀ because the gate bias voltage V_{Bias} received at the node 606b is sourced to ground via the diodes Dₐ¹⁻ⁿ when the MEMS gate control switch M_{MEM} is enabled.

At time t₁, the input isolation switch M_{Bypass} is briefly enabled by the gate control signal 902a to sink the input voltage at node 606a to a voltage bias node, such as ground (e.g., for 10 microseconds or less). The maximum amount of time that the input isolation switch M_{Bypass} can be enabled is determined by the current carrying capacity of the input isolation switch M_{Bypass} since it will effectively short the input voltage at node 606a to ground.

Additionally, at time t₁ the output current switch M_{Curr} is enabled by the gate control signal 902b to connect node 606d of the switch 604 to ground. As shown with reference to FIGS. 7-8, when nodes 606a and 606d are both tied to ground, no current will flow therebetween. Also, because the MEMS gate control switch M_{MEM} is enabled, there is no voltage differential across the Gate and Beam nodes of the MEMS switches SW¹⁻ⁿ, and the MEMS switches SW¹⁻ⁿ are therefore disabled.

At time t₂, the MEMS gate control signal Gate_{MEM} 902c is de-asserted, thereby turning the gate control switch M_{MEM} off and allowing the gate bias voltage V_{Bias} to reach the Gate nodes of the MEMS switches SW¹⁻ⁿ to turn the switch 604 on. Because the switch 604 is enabled while the input voltage Vᵢₙ at node 606a is bypassed to ground, hot-switching is advantageously avoided for the switch 604.

At time t₃, the input isolation switch M_{Bypass} is disabled by the gate control signal 902a so as to no longer sink the input voltage at node 606a to ground, and current thereafter flows between the node 606a to ground via the enabled MEMS switches SW¹⁻ⁿ and the enabled output current switch M_{Curr}. The gate control signals 902a-c may remain in the same state at time t₄ to maintain the switch 604 in an on state.

FIG. 9B provides an example switching sequence 904 that advantageously prevents hot-switching of the high-voltage MEMS switch (“switch”) 604 while disabling the high-voltage MEMS switch 604 (which could be implemented as either the high-voltage MEMS switch 704 or 804), in accordance with some examples.

With reference to FIG. 6, FIG. 9B provides a plot 906a of the gate control signal Gate_{Bypass} of the input isolation switch M_{Bypass}, a plot 906b of the gate control signal Gate_{Curr} of the output current switch M_{Curr}, and a plot 906c of the gate control signal Gate_{MEM} of the MEMS gate control switch M_{MEM}. In some examples, the gate control signals 906a-c are generated by a switch control circuit, such as the switch control circuit 102 introduced in FIG. 1.

At time t₀, the gate control signals Gate_{Bypass} 906a and Gate_{MEM} 906c are de-asserted, and the gate control signal Gate_{Curr} 906b is asserted, thereby maintaining the switch 604 in an on state. That is, with reference to FIGS. 7-8, the switch 604 is in an on state at time t₀ because the gate control signal Gate_{MEM} 906c for the MEMS gate control switch M_{MEM} is de-asserted, thereby turning the gate control switch M_{MEM} off and allowing the gate bias voltage V_{Bias} to reach the gate nodes of the MEMS switches SW¹⁻ⁿ to maintain an enabled state for the switch 604. Similarly, because the input isolation switch M_{Bypass} is disabled via the de-asserted gate signal Gate_{Bypass} 906a, the input voltage Vᵢₙ is present at the node 606a, and current flows between the node 606a to ground via the enabled MEMS switches SW¹⁻ⁿ and the enabled output current switch M_{Curr}.

At time t₁, the input isolation switch M_{Bypass} is enabled by gate control signal 906a to briefly sink the input voltage at node 606a to a voltage bias node, such as ground (e.g., for 10 microseconds or less). As shown with reference to FIGS. 7-8, when nodes 606a and 606d are both tied to ground at time t₁, no current will flow therebetween.

At time t₂, the MEMS gate control signal Gate_{MEM} 906c is asserted and gate control signal Gate_{Curr} 906b is de-asserted, thereby placing the switch 604 in an off state by sinking the gate bias voltage V_{Bias} received at the node 606b to ground via the diodes Dₐ¹⁻ⁿ and the enabled gate control switch M_{MEM}. Because the switch 604 is disabled while the input voltage Vᵢₙ at node 606a is bypassed to ground, hot-switching is advantageously avoided for the switch 604.

At time t₃, the input isolation switch M_{Bypass} is disabled by gate control signal Gate_{Bypass} 906a so as to no longer sink the input voltage at node 606a to ground.

The gate control signals 906a-c may thereafter remain in the same state at time t₄ to maintain the switch 604 in an off state.

In any of the topologies 310, 312, 410, 412, 510, and 512 disclosed herein, a resistor may be placed in series with the Zener diode(s) thereof to reduce gate bias variations when currents are in the MEMS switch 204.

In some examples, a first one or more of the topologies 310, 312, 410, 412, 510, and 512 may be placed in a parallel circuit arrangement with a second one of the topologies 310, 312, 410, 412, 510, and 512.

In some examples, a first one or more of the topologies 310, 312, 410, 412, 510, and 512 may be placed in a series circuit arrangement with a second one of the topologies 310, 312, 410, 412, 510, and 512.

In some examples, a first one or more of the topologies 310, 312, 410, 412, 510, and 512 may be placed in a series circuit arrangement with a second one of the topologies 310, 312, 410, 412, 510, and 512, and in a parallel circuit arrangement with a third one of the topologies 310, 312, 410, 412, 510, and 512.

In some examples, a first one or more of the topologies 310, 312, 410, 412, 510, and 512 may be placed in a parallel or series circuit arrangement with a second one of the topologies 310, 312, 410, 412, 510, and 512, the first and second topologies being isolated by current steering diodes.

In some examples, each of the topologies 310, 312, 410, 412, 510, and 512 may be turned off and on by use of two steering diodes and pull-down active devices, such as but not limited to, BJT or MOSFET active devices.

In some examples, the Zener diode(s) of each of the topologies 310, 312, 410, 412, 510, and 512 may have a reverse breakdown voltage V_{Zener} that is close to, or the same as, an actuation voltage threshold of the MEMS switch 204.

In some examples, the reverse breakdown voltage V_{Zener} values and resistance values of each of the topologies 310, 312, 410, 412, 510, and 512 may be selected to minimize voltage variations across the Zener diode thereof with respect to variations in supply voltage to the respective MEMS switch 204.

In any of the topologies 310, 312, 410, 412, 510, and 512 disclosed herein, a capacitor may be placed in parallel with the Zener diode(s) thereof to stabilize the circuit due to transients.

In any of the topologies 310, 312, 410, 412, 510, and 512 disclosed herein, a resistor may be placed in parallel with the Zener diode(s) thereof to help hold the value across the MEMS gate at zero volts when the MEMS switch is not actuated.

In any of the topologies 310, 312, 410, 412, 510, and 512 disclosed herein, a capacitor and resistor may be placed in parallel with the Zener diode(s) to adjust the RC time constant across the MEMS gate.

In some examples, any of the topologies 310, 312, 410, 412, 510, 512, 600, 704, and 804 may be used as part of a circuit breaker circuit.

Reference has been made in detail to examples of the disclosed invention, one or more examples of which have been illustrated in the accompanying figures. Each example has been provided by way of explanation of the present technology, not as a limitation of the present technology. In fact, while the specification has been described in detail with respect to specific examples of the invention, it will be appreciated that those skilled in the art, upon attaining an understanding of the foregoing, may readily conceive of alterations to, variations of, and equivalents to these examples. For instance, features illustrated or described as part of one example may be used with another example to yield a still further example. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. An apparatus comprising:
a first microelectromechanical systems (MEMS) switch having an input node, an output node, a gate node, and a beam node;
a first Zener diode having a first terminal directly electrically connected to the gate node of the first MEMS switch, the first terminal being one of an anode terminal or a cathode terminal of the first Zener diode; and
a first pull-down resistor having a first terminal directly electrically connected to the gate node of the first MEMS switch and a second terminal directly electrically connected to a bias voltage at a first voltage node;
wherein the first Zener diode is configured to limit a magnitude of a bias voltage difference between the gate node and the beam node of the first MEMS switch to be not greater than a voltage level that is about equal to a breakdown voltage of the first Zener diode, the breakdown voltage being selected to be at or slightly above an actuation voltage threshold of the first MEMS switch; and
wherein the first pull-down resistor is configured to pull the gate node toward the bias voltage when the magnitude of the bias voltage difference between the gate node and the beam node is less than the actuation voltage threshold of the first MEMS switch.

2. The apparatus of claim 1, wherein:
the bias voltage at the first voltage node is ground.

3. The apparatus of claim 1, wherein:
the first terminal of the first Zener diode is the anode terminal of the first Zener diode, and the cathode terminal of the first Zener diode is directly electrically connected to the beam node of the first MEMS switch.

4. The apparatus of claim 1, wherein:
the first terminal of the first Zener diode is the cathode terminal of the first Zener diode, and the anode terminal of the first Zener diode is directly electrically connected to the beam node of the first MEMS switch.

5. The apparatus of claim 1, wherein:
the first terminal of the first Zener diode is the cathode terminal of the first Zener diode, and the anode terminal of the first Zener diode is directly electrically connected to the output node of the first MEMS switch.

6. The apparatus of claim 1, wherein:
the first terminal of the first Zener diode is the anode terminal of the first Zener diode, and the cathode terminal of the first Zener diode is directly electrically connected to the output node of the first MEMS switch.

7. The apparatus of claim 1, further comprising:
a second Zener diode having a respective anode terminal and a respective cathode terminal;
wherein:
the first terminal of the first Zener diode is the cathode terminal of the first Zener diode, and the anode terminal of the first Zener diode is directly electrically connected to the anode terminal of the second Zener diode, the cathode terminal of the second Zener diode being directly electrically connected to the input node of the first MEMS switch.

8. The apparatus of claim 1, further comprising:
a second Zener diode having a respective anode terminal and a respective cathode terminal;
wherein:
the first terminal of the first Zener diode is the cathode terminal of the first Zener diode, and the anode terminal of the first Zener diode is directly electrically connected to the anode terminal of the second Zener diode, the cathode terminal of the second Zener diode being directly electrically connected to the output node of the first MEMS switch.

9. The apparatus of claim 1, further comprising:
a first series resistor having a first terminal that is configured to receive a gate bias voltage and a second terminal that is directly electrically connected to a respective anode terminal of a first current steering diode and to a respective anode terminal of a second current steering diode, a respective cathode terminal of the first current steering diode being directly electrically connected to the gate node of the first MEMS switch;
a first capacitor having a first terminal that is directly electrically connected to the gate node of the first MEMS switch and a second terminal that is directly electrically connected to the output node of the first MEMS switch;
a first parallel diode having a cathode terminal that is directly electrically connected to the input node of the first MEMS switch and an anode terminal that is directly electrically connected to the output node of the first MEMS switch; and
a first parallel resistor having a first terminal that is directly electrically connected to the input node of the first MEMS switch and a second terminal that is directly electrically connected to the output node of the first MEMS switch.

10. The apparatus of claim 9, further comprising:
a second MEMS switch having a respective input node, a respective output node, a respective gate node, and a respective beam node, the input node of the second MEMS switch being directly electrically connected to the output node of the first MEMS switch;
a second Zener diode having a respective cathode terminal directly electrically connected to the gate node of the second MEMS switch and a respective anode terminal directly electrically connected to the output node of the second MEMS switch;
a second pull-down resistor having a respective first terminal directly electrically connected to the gate node of the second MEMS switch and a respective second terminal directly electrically connected to the output node of the second MEMS switch and to a respective bias voltage at a respective second voltage node;
a second series resistor having a first terminal that is configured to receive the gate bias voltage and a second terminal that is directly electrically connected to a respective anode terminal of a third current steering diode and to a respective anode terminal of a fourth current steering diode, a respective cathode terminal of the third current steering diode being directly electrically connected to the gate node of the second MEMS switch;
a second capacitor having a first terminal that is directly electrically connected to the gate node of the second MEMS switch and a second terminal that is directly electrically connected to the output node of the second MEMS switch;
a second parallel diode having a cathode terminal that is directly electrically connected to the input node of the second MEMS switch and to the anode terminal of the first parallel diode, and an anode terminal that is directly electrically connected to the output node of the second MEMS switch; and
a second parallel resistor having a first terminal that is directly electrically connected to the input node of the second MEMS switch and the second terminal of the first parallel resistor, and a second terminal that is directly electrically connected to the output node of the second MEMS switch.

11. The apparatus of claim 10, wherein:
the input node of the first MEMS switch is configured to be directly electrically connected to an input isolation switch that is operable to selectively provide an input voltage or ground to the input node of the first MEMS switch; and
the respective cathode terminals of the first current steering diode and the second current steering diode are configured to be directly electrically connected to a gate control switch that is operable to selectively provide a gate bias voltage to the respective gate nodes of the first MEMS switch and the second MEMS switch.

12. The apparatus of claim 11, wherein enabling the first MEMS switch and the
second MEMS switch comprises:
preventing, using the gate control switch, the gate bias voltage from reaching the respective gate nodes of the first MEMS switch and the second MEMS switch at a first time;
providing, using the input isolation switch, ground to the input node of the first MEMS switch at a second time;
allowing, using the gate control switch, the gate bias voltage to reach the respective gate nodes of the first MEMS switch and the second MEMS switch at a third time that is after the first time and the second time; and
providing, using the input isolation switch, the input voltage to the input node of the first MEMS switch at a fourth time that is after the third time.

13. The apparatus of claim 11, wherein disabling the first MEMS switch and the
second MEMS switch comprises:
providing, using the input isolation switch, ground to the input node of the first MEMS switch at a first time;
preventing, using the gate control switch, the gate bias voltage from reaching the respective gate nodes of the first MEMS switch and the second MEMS switch at a second time that is after the first time; and
providing, using the input isolation switch, the input voltage to the input node of the first MEMS switch at a third time that is after the second time.

14. An apparatus comprising:
a first microelectromechanical systems (MEMS) switch having an input node, an output node, a gate node, and a beam node;
an optional first Zener diode having a first terminal directly electrically connected to the gate node of the first MEMS switch, the first terminal being one of an anode terminal of the optional first Zener diode or a cathode terminal of the optional first Zener diode; and
a first pull-down resistor having a first terminal directly electrically connected to the gate node of the first MEMS switch and a second terminal directly electrically connected to a bias voltage at a first voltage node.

15. The apparatus of claim 14, wherein:
the bias voltage at the first voltage node is ground.

16. The apparatus of claim 14, further comprising:
a first series resistor having a first terminal that is configured to receive a gate bias voltage and a second terminal that is directly electrically connected to a respective anode terminal of a first current steering diode and to a respective anode terminal of a second current steering diode, a respective cathode terminal of the first current steering diode being directly electrically connected to the gate node of the first MEMS switch;
a first capacitor having a first terminal that is directly electrically connected to the gate node of the first MEMS switch and a second terminal that is directly electrically connected to the output node of the first MEMS switch;
a first parallel diode having a cathode terminal that is directly electrically connected to the input node of the first MEMS switch and an anode terminal that is directly electrically connected to the output node of the first MEMS switch; and
a first parallel resistor having a first terminal that is directly electrically connected to the input node of the first MEMS switch and a second terminal that is directly electrically connected to the output node of the first MEMS switch.

17. The apparatus of claim 16, further comprising:
a second MEMS switch having a respective input node, a respective output node, a respective gate node, and a respective beam node, the input node of the second MEMS switch being directly electrically connected to the output node of the first MEMS switch;
an optional second Zener diode having a respective cathode terminal directly electrically connected to the gate node of the second MEMS switch and a respective anode terminal directly electrically connected to the output node of the second MEMS switch;
a second pull-down resistor having a respective first terminal directly electrically connected to the gate node of the second MEMS switch and a respective second terminal directly electrically connected to the output node of the second MEMS switch and to a respective bias voltage at a respective second voltage node;
a second series resistor having a first terminal that is configured to receive the gate bias voltage and a second terminal that is directly electrically connected to a respective anode terminal of a third current steering diode and to a respective anode terminal of a fourth current steering diode, a respective cathode terminal of the third current steering diode being directly electrically connected to the gate node of the second MEMS switch;
a second capacitor having a first terminal that is directly electrically connected to the gate node of the second MEMS switch and a second terminal that is directly electrically connected to the output node of the second MEMS switch;
a second parallel diode having a cathode terminal that is directly electrically connected to the input node of the second MEMS switch and to the anode terminal of the first parallel diode, and an anode terminal that is directly electrically connected to the output node of the second MEMS switch; and
a second parallel resistor having a first terminal that is directly electrically connected to the input node of the second MEMS switch and the second terminal of the first parallel resistor, and a second terminal that is directly electrically connected to the output node of the second MEMS switch.

18. The apparatus of claim 16, wherein:
the input node of the first MEMS switch is configured to be directly electrically connected to an input isolation switch that is operable to selectively provide an input voltage or ground to the input node of the first MEMS switch; and
the respective cathode terminals of the first current steering diode and the second current steering diode are configured to be directly electrically connected to a gate control switch that is operable to selectively provide a gate bias voltage to the respective gate nodes of the first MEMS switch and the second MEMS switch.

19. The apparatus of claim 18, wherein enabling the first MEMS switch and the
second MEMS switch comprises:
preventing, using the gate control switch, the gate bias voltage from reaching the respective gate nodes of the first MEMS switch and the second MEMS switch at a first time;
providing, using the input isolation switch, ground to the input node of the first MEMS switch at a second time;
allowing, using the gate control switch, the gate bias voltage to reach the respective gate nodes of the first MEMS switch and the second MEMS switch at a third time that is after the first time and the second time; and
providing, using the input isolation switch, the input voltage to the input node of the first MEMS switch at a fourth time that is after the third time.

20. The apparatus of claim 18, wherein disabling the first MEMS switch and the
second MEMS switch comprises:
providing, using the input isolation switch, ground to the input node of the first MEMS switch at a first time;
preventing, using the gate control switch, the gate bias voltage from reaching the respective gate nodes of the first MEMS switch and the second MEMS switch at a second time that is after the first time; and
providing, using the input isolation switch, the input voltage to the input node of the first MEMS switch at a third time that is after the second time.
